(19) United States
(12) Patent Application Publication
(10) Pub. No.: US 2006/0003491 A1
(43) Pub. Date: Jan. 5, 2006

(54) Apparatus for ejecting relatively thin IC chip from semiconductor wafer

(76) Inventors: Goon-Woo Kim, Chungcheongnam-do (KR); Heui-Seog Kim, Chungcheongnam-do (KR); Jong-Keun Jeon, Chungcheongnam-do (KR); Wha-Su Sin, Chungcheongnam-do (KR); Jong-Ung Lee, Chungcheongnam-do (KR)

Correspondence Address: MARGER JOHNSON & McCOLLOM, P.C, 1030 S.W. Morrison Street, Portland, OR, 97205, US

(21) Appl. No.: 11/153,750

(22) Filed: Jun. 14, 2005

(30) Foreign Application Priority Data
Jul. 5, 2004 (KR) 2004-0051957

(51) Int. Cl. H01L 21/44

(52) U.S. Cl. 438/106

(57) ABSTRACT

An apparatus and method for ejecting a thin IC chip from a UV-sensitive tape attached to a bottom face of a semiconductor wafer, includes a vacuum holder that partly supports the UV-sensitive tape by applying vacuum force. The apparatus further includes an ejecting block inserted in the vacuum holder and configured to move vertically relative to the vacuum holder, and a plurality of ejecting pins inserted in the ejecting block and configured to move vertically and elastically. The ejecting pins move upward from the ejecting block driven by a pin-driving plate, detaching the IC chip from the UV-sensitive tape. Then the ejecting block moves upward from the vacuum holder driven by a block-driving shaft, applying a pressure to the bottom face of the IC chip.

### CROSS REFERENCE TO RELATED APPLICATIONS

This U.S. non-provisional application claims priority under 35 U.S.C. §119 from Korean Patent Application No. 2004-51957, which was filed in the Korean Intellectual Property Office on Jul. 5, 2004, the contents of which are incorporated by reference herein in its entirety.

### BACKGROUND OF THE INVENTION

1. Field of the Invention

The present invention relates generally to electronic packaging technology and, more particularly, to an apparatus for ejecting relatively thin IC chips from a semiconductor wafer in a chip separation process.

2. Description of the Related Art

Integrated circuits (IC) are reaching the limit of minimization, and further, two-dimensional wafers restrict the rise in degree of integration of IC chips. Three-dimensional (3-D) stacking technology is therefore being studied to provide higher integration density.

A great number of IC chips are simultaneously fabricated on the wafer during the wafer fabrication process. Each individual IC chip is then separated from the wafer and vertically stacked in a bare form or a package form. Such 3-D stacking is inevitably confronted with an increase in thickness of stack. So, 3-D stacking often requires a relatively thin IC chip. The thin IC chip is, however, very susceptible to mechanical shocks during separation or handling.

FIG. 1 shows, in a cross-sectional view, a conventional apparatus 10 for ejecting the thin IC chip 22 from the wafer 20 during separation of the IC chip 22.

Referring to FIG. 1, after the wafer fabrication process is completed, the wafer 20 undergoes an electrical die sorting (EDS) process and wafer sawing process. In the wafer sawing process, the wafer 20 is sawed along scribe lines and thereby the individual IC chips 22 are divided from each other. The divided individual IC chips 22 are temporarily supported by an adhesive tape 23 attached in advance to the bottom face of the wafer 20. Typically, the adhesive tape 23 is a UV-sensitive tape that has high adhesive strength and is highly expandable. When exposed to UV rays, the UV-sensitive tape 23 can lose adhesive strength.

To completely separate the individual IC chip 22 from the wafer 20, the chip-ejecting apparatus 10 is used together with UV exposure. The chip-ejecting apparatus 10 is located under the wafer 20, and a vacuum holder 11 supports the UV-sensitive tape 23 by applying a vacuum force. Then ejecting pins 13 move upward by the ascent of a pin-driving plate 14 and push up on the IC chip 22. In addition, a chip-transferring tool 30 pulls the IC chip 22 by vacuum force, keeping in contact with the top face of the IC chip 22.

Although the UV-sensitive tape 23 is exposed to UV rays so as to reduce the adhesive strength, the UV-sensitive tape 23 still has some residual adhesive strength. Such residual adhesion is not a problem in the case of a normal, relatively thick IC chip. However, adhesion becomes an issue in the case of the relatively thin IC chip 22 having a thickness of about 801 μm and less. While the ejecting pins 13 still exert a force enough to detach the IC chip 22 from the UV-sensitive tape 23, such a force exerted by the ejecting pins 13 may be too strong for the thin IC chip 22. Since the IC chip 22 is mainly made of silicon which is inherently brittle, the thin IC chip 22 may often succumb to the mechanical stress caused by the chip-ejecting force and, therefore, may be cracked or broken.

The thin IC chip 22 may further encounter another problem during separation. The above-discussed residual adhesion of the UV-sensitive tape 23 may also unfavorably affect the planarity of the thin IC chip 22 and therefore warp the IC chip 22. Such warpage may invite a poor placement of the thin IC chip 22 on a next-level substrate, and may also lead to defective wire bonding between the IC chip and the substrate.

Some attempts to relieve mechanical stress applied to the thin IC chip have been disclosed in Korean Utility Model No. 194288 and Korean Patent Nos. 142152 and 206911, for example. According to these disclosures, the ejecting pins are vested with elasticity to reduce mechanical stress. However, the foregoing problem relating to chip warpage is still unsettled.

### SUMMARY OF THE INVENTION

Embodiments of the present invention provide an apparatus and method for ejecting a thin IC chip from a UV-sensitive tape that is attached to a bottom face of a semiconductor wafer.

In one embodiment, the chip ejecting apparatus includes a vacuum holder, an ejecting block, and a plurality of ejecting pins. The vacuum holder is adapted to support the UV-sensitive tape by applying a vacuum force to the UV-sensitive tape. The ejecting block is positioned in the vacuum holder and configured to move vertically relative to the vacuum holder. The plurality of ejecting pins are inserted in a corresponding plurality of pin holes located in the ejecting block and are configured to move vertically and elastically relative to the ejecting block. The ejecting pins are adapted to move upward from the ejecting block to position the ejecting pins against the UV-sensitive tape below the IC chip to be ejected. The ejecting block is adapted to then move upward from the vacuum holder to position the ejecting block across a bottom surface of the IC chip.

Another embodiment provides a method of separating an IC chip from a semiconductor wafer. The sawed IC chip is supported on a UV-sensitive tape. A vacuum force is applied to a bottom surface of the UV-sensitive tape in an area below the chip. A vacuum force is applied to a top surface of the IC chip with a chip transferring tool. The adhesion of the UV-sensitive tape is reduced by exposing the tape to UV rays. The IC chip is pushed upward from the wafer by applying a plurality of point forces to the bottom surface of the UV-sensitive tape with a plurality of ejecting pins. The IC chip is then pressed against the chip transferring tool to eliminate or reduce warping of the chip by applying a surface pressure across a bottom surface of the IC chip with an ejecting block moving upward to the bottom surface of the IC chip. The vacuum force is removed from the bottom surface of the UV-sensitive tape, and the IC chip is transferred to a next place by the chip transferring tool.

### BRIEF DESCRIPTION OF THE DRAWINGS

FIG. 1 is a cross-sectional view of a conventional apparatus for ejecting a thin IC chip from a wafer.

FIG. 2 is a top plan view of an apparatus for ejecting a thin IC chip from a wafer according to an embodiment of the present invention.

FIG. 3 is a cross-sectional view taken along the line III-III of FIG. 2.

FIG. 4 is a cross-sectional view of an ejecting pin of the chip-ejecting apparatus 50 of FIG. 2.

FIG. 5 is a top plan view showing a wafer loaded on a wafer table for chip separation;

FIG. 6 is a cross-sectional view showing a vacuum holder partly supporting UV-sensitive tape;

FIG. 7 is a cross-sectional view showing ejecting pins pushing up a thin IC chip;

FIG. 8 is a cross-sectional view showing that an ejecting block applying a pressure to the bottom face of the thin IC chip; and

FIG. 9 is a cross-sectional view showing a chip-transferring tool transferring the thin IC chip.

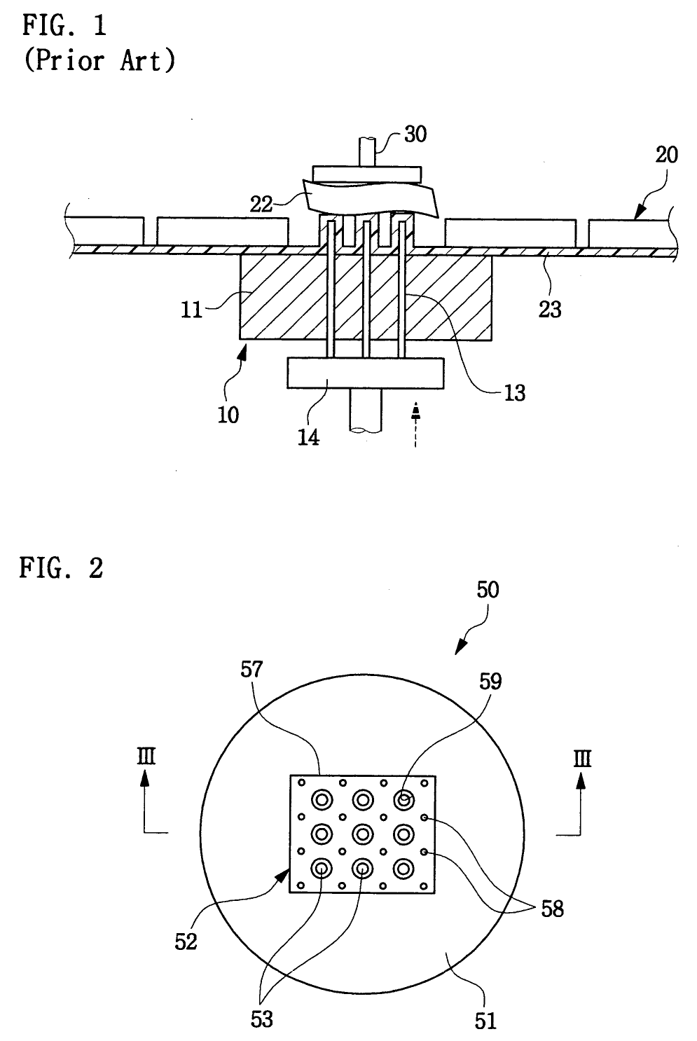

### DETAILED DESCRIPTION

Exemplary, non-limiting embodiments of the present invention will now be described more fully hereinafter with reference to the accompanying drawings. This invention may, however, be embodied in many different forms and should not be construed as limited to the exemplary embodiments set forth herein. Rather, the disclosed embodiments are provided so that this disclosure will be thorough and complete, and will fully convey the scope of the invention to those skilled in the art. The principles and feature of this invention may be employed in varied and numerous embodiments without departing from the scope of the invention.

In this disclosure, well-known structures and processes are not described or illustrated in detail to avoid obscuring the present invention. Furthermore, the figures are not drawn to scale in the drawings. Rather, for simplicity and clarity of illustration, the dimensions of some of the elements are exaggerated relative to other elements. Like reference numerals are used for like and corresponding parts of the various drawings.

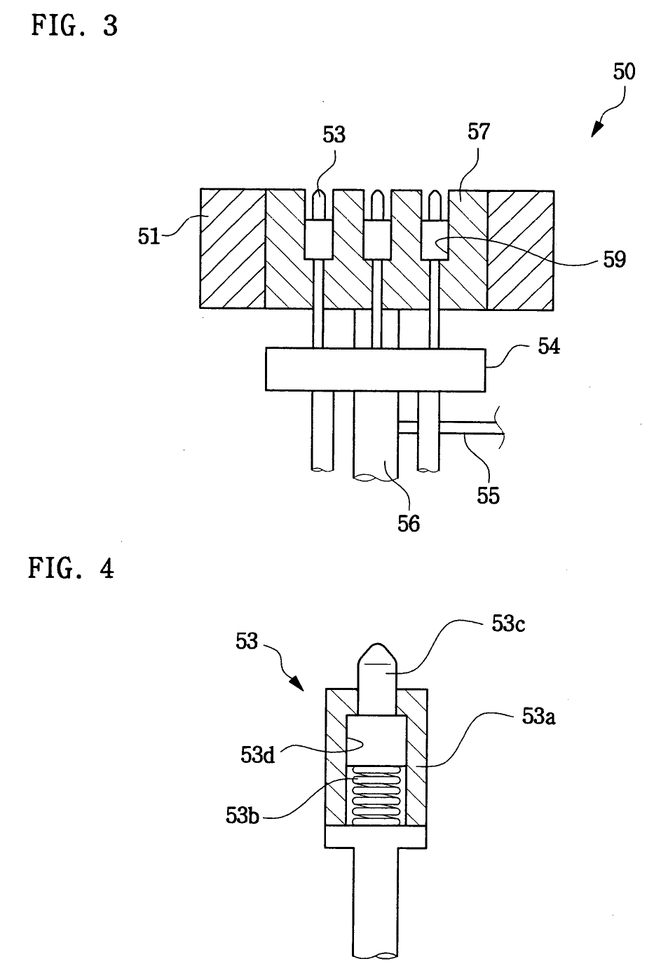

FIG. 2 is a top plan view of an apparatus 50 for ejecting a thin IC chip from a wafer according to an embodiment of the present invention. FIG. 3 is a cross-sectional view taken along the line III-III of FIG. 2. In addition, FIG. 4 is a cross-sectional view of an ejecting pin 53 of the chip-ejecting apparatus of FIG. 2.

Referring to FIGS. 2 to 4, the thin IC chip ejecting apparatus 50 includes a vacuum holder 51 and a dual ejecting unit 52. The vacuum holder 51 supports, by applying vacuum force, parts of a UV-sensitive tape around the targeted IC chip to be ejected. The dual ejecting unit 52, which is placed at the central region of the vacuum holder 51, ejects the individual thin IC chip from the UV-sensitive tape. The dual ejecting unit 52 has several ejecting pins 53, a pin-driving plate 54, a vacuum hose 55, a block-driving shaft 56, and an ejecting block 57.

The ejecting block 57 is movably inserted in the central region of the vacuum holder 51 and configured to move vertically. Further, the ejecting block 57 is connected to the block-driving shaft 56, which is located under the ejecting block 57 and supplies motive force to the ejecting block 57. As will be described later, the ejecting block 57 is a tool for applying a pressure to the bottom face of the IC chip so as to compensate the warpage of the IC chip. The ejecting block 57 has a number of vacuum holes 58 and pin holes 59, which are regularly arranged. The ejecting block 57 may have a size, in a plan view, substantially equal to or smaller than that of the IC chip.

The vacuum holes 58 can communicate with the vacuum hose 55 directly or through the block-driving shaft 56. The vacuum hose 55 is configured such that the pin-driving plate 54 does not interfere with the vacuum hose 55. Each individual pin hole 59 contains an ejecting pin 53. The ejecting pins 53 are movably inserted in the pin holes 59, respectively and configured to move vertically and elastically. Further, the ejecting pins 53 are connected to the pin-driving plate 54, which is located under the ejecting pins 53 and supplies motive force to the ejecting pins 53. As will be described later, the ejecting pins 53 are tools for pushing up an IC chip to detach the IC chip from the UV-sensitive tape.

Referring to FIG. 4, each individual ejecting pin 53 has a pin holder 53a, an elastic member 53b, and a pin head 53c. The pin holder 53a has a cylindrical shape with a hollow area 53d inside. The elastic member 53b and a lower part of the pin head 53c are located in the hollow area 53d of the pin holder 53a. The elastic member 53b, such as a spring, underlies the pin head 53c and provides an upward elastic force to the pin head 53c. An upper part of the pin head 53c protrudes from the pin holder 53a by elastic force of the elastic member 53b. The pin head 53c can move downward, compressing the elastic member 53b. Such elastic movement of the pin head 53c can reduce the mechanical stress applied to the thin IC chip.

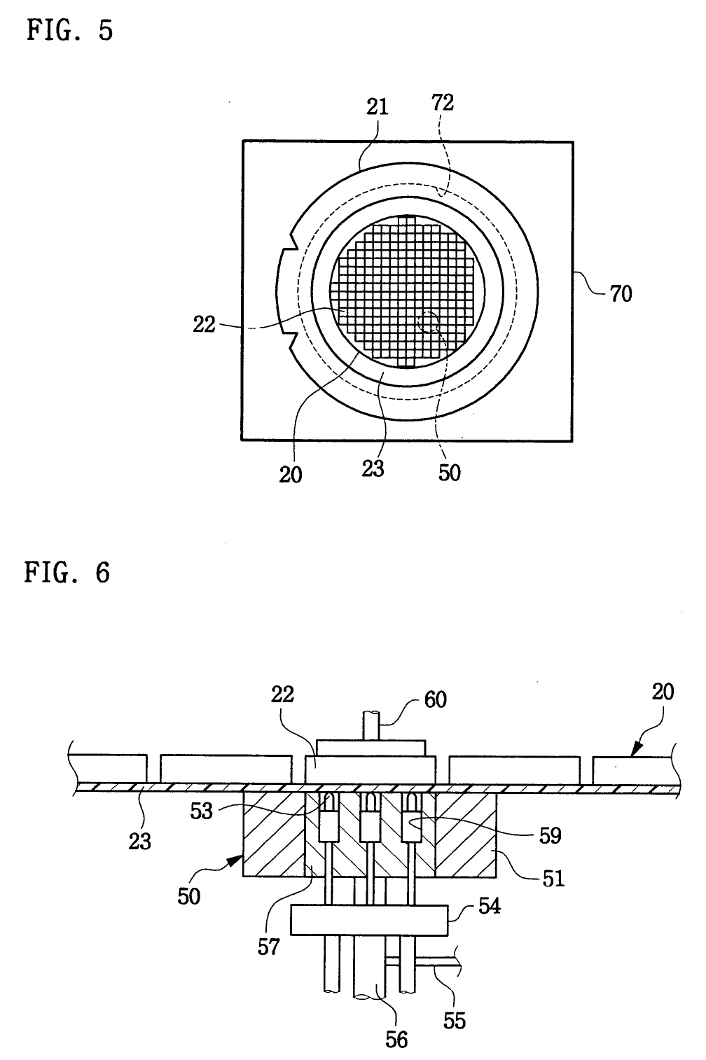

FIGS. 5 to 9 show in sequence a method for ejecting the thin IC chip 22 from the UV-sensitive tape 23 by using the above-discussed ejecting apparatus 50.

FIG. 5 shows, in a top plan view, the wafer 20 loaded on a wafer table 70 for chip separation. As shown in FIG. 5, the wafer 20, after completing the wafer sawing process, is positioned on the wafer table 70. The wafer 20 is surrounded with and temporarily supported on a wafer ring 21 by UV-sensitive tape 23. The wafer 20 has a number of the IC chips 22 divided from each other by sawing, and the individual IC chips 22 remain on the Uv-sensitive tape 23. The wafer 20, i.e., the IC chips 22, has a relatively thin thickness of about 80 μm or less. The UV-sensitive tape 23 has high adhesive strength and is highly expandable, but loses adhesive strength when exposed to UV rays.

The wafer table 70 includes a hollow circular center 72. The wafer 20 loaded on the wafer table 70 is located over the hollow circular center 72, and further, the above-discussed ejecting apparatus 50 is located within the hollow circular center 72 under the wafer 20.

After the wafer 20 is loaded on the wafer table 70, the vacuum holder 51 of the ejecting apparatus 50 partly supports the UV-sensitive tape 23, as shown in FIG. 6. Referring to FIG. 6, the ejecting apparatus 50 moves under a targeted one of the individual IC chips 22, and the vacuum holder 51 supports parts of the UV-sensitive tape 23 around the targeted IC chip 22 to be ejected by applying a vacuum force to the UV-sensitive tape 23. Further, the ejecting block 57 in the vacuum holder 51 also supports the UV-sensitive tape 23 underneath the targeted IC chip 22 though the vacuum holes 58 (see FIG. 2).

In addition, a chip-transferring tool 60 located above the wafer 20 moves onto the targeted IC chip 22 and is placed in contact with the top face of the IC chip 22. By doing so, the chip-transferring tool 60 can prevent an undesirable shift in position of the IC chip 22 or an accidental fall of the IC chip 22 when the IC chip 22 is ejected from the UV-sensitive tape 23.

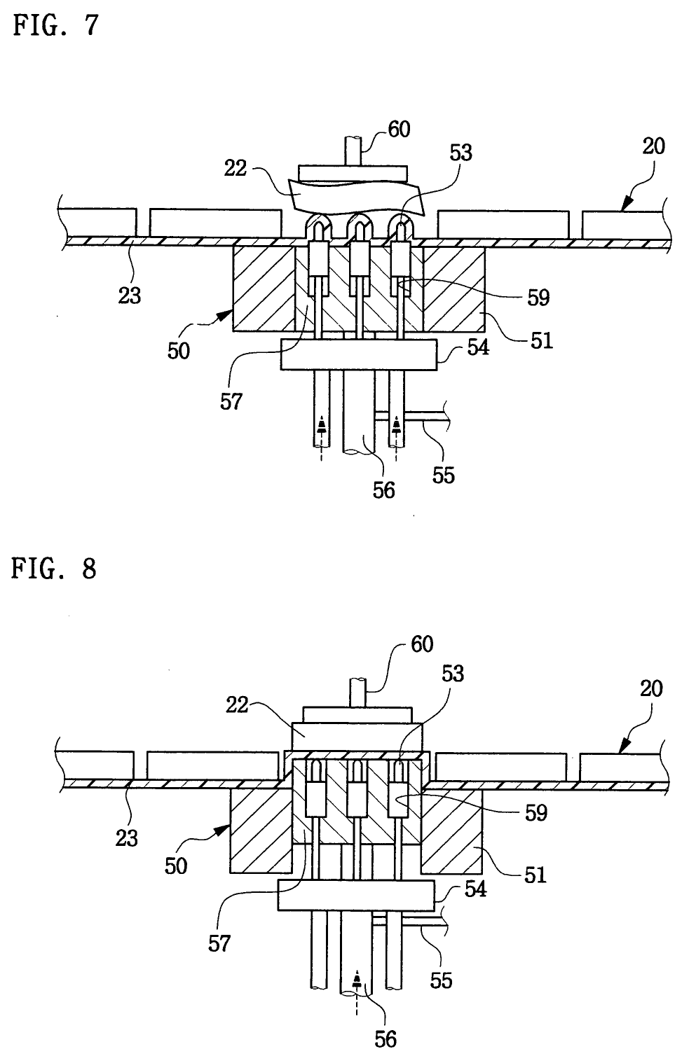

After the UV-sensitive tape 23 is supported, the ejecting pins 53 push up the IC chip 22, as shown in FIG. 7. Referring to FIG. 7, the ejecting pins 53 inserted in the ejecting block 57 move upward, pushed by the pin-driving plate 54, applying point forces to the underside of the IC chip 22. The IC chip 22 is, therefore, detached from the LW-sensitive tape 23.

As discussed above, the ejecting pin 53 can move elastically. Referring to FIGS. 4 and 7, the pin head 53c protruding from the pin holder 53a meets the UV-sensitive tape 23. Thereafter, when the pin-driving plate 54 moves upward, the ejecting pin 53 is pushed upward from the ejecting block 57. At this time, the pin head 53c resists moving upward due to the UV-sensitive tape 23 compressing the elastic member 53b. Such elastic movement of the pin head 53c reduces mechanical stress applied to the thin IC chip 22. While the ejecting pins 53 push up the bottom face of the IC chip 22, the chip-transferring tool 60 also moves upward while still keeping in contact with the top face of the IC chip 22. In the meantime, the ejected IC chip 22 may be unfavorably warped due to the residual adhesion of the UV-sensitive tape 23, as discussed above.

Subsequently, the ejecting block 57 moves upward and applies a pressure to the bottom face of the IC chip 22, as shown in FIG. 8. Referring to FIG. 8, the block-driving shaft 56 pushes up the ejecting block 57, so the ejecting block 57 moves upward from the vacuum holder 51. Then the ejecting block 57 applies a pressure to the bottom face of the IC chip 22, and further, the chip-transferring tool 60 applies a pressure to the top face of the IC chip 22. By doing so, a warped IC chip 22 returns to a flat state. Moreover, since the ejecting block 57 keeps in contact with the entire bottom face of the IC chip 22, the ejecting block 57 can disperse mechanical stress potentially remaining in the IC chip 22 throughout the entire bottom face.

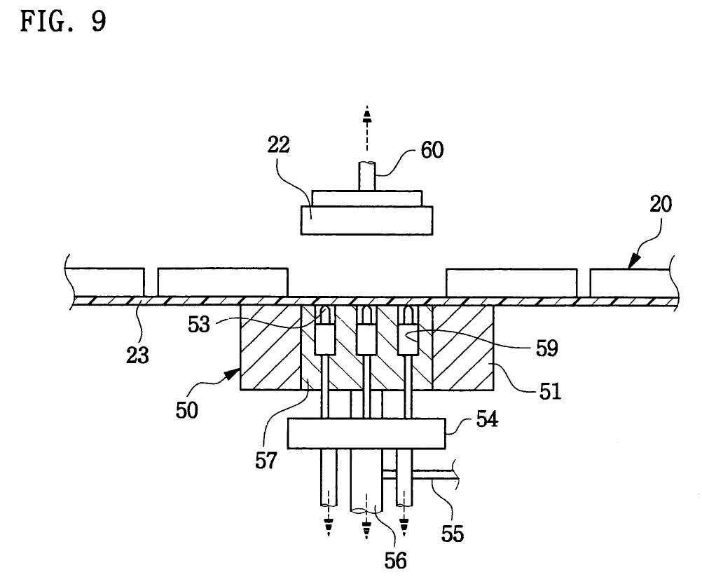

After the ejecting block 57 moves upward, the chip-transferring tool 60 carries the ejected IC chip 22, as shown in FIG. 9. Referring to FIG. 9, the vacuum hose 55 stops supplying vacuum force to vacuum holes 58, and the chip-transferring tool 60 supports the IC chip 22 by applying vacuum force. Then the chip-transferring tool 60 transfers the IC chip 22 to a next place for a chip-attaching process. Meanwhile, the ejecting pins 53 and the ejecting block 57 return to their original position.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. An integrated circuit (IC) chip ejecting apparatus, comprising:
an ejecting block positioned to support a UV-sensitive tape on a semiconductor wafer and configured to move vertically; and
a plurality of ejecting pins movably inserted in a corresponding plurality of pin holes located in the ejecting block and configured to move vertically and elastically relative to the ejecting block,
wherein the ejecting pins are adapted to move upward from the ejecting block to position the ejecting pins against the UV-sensitive tape below the IC chip, and the ejecting block is adapted to move upward to position the ejecting block across a bottom surface of the IC chip.

2. The apparatus of claim 1, further comprising a vacuum holder adapted to apply a vacuum force to the UV-sensitive tape,
wherein the ejecting block is positioned in the vacuum holder.

3. The apparatus of claim 1, further comprising a block-driving shaft positioned under and connected to the ejecting block, and adapted to supply a motive force to the ejecting block.

4. The apparatus of claim 1, further comprising a pin-driving plate positioned under and connected to the ejecting pins, and adapted to a supply a motive force to the ejecting pins.

5. The apparatus of claim 1, wherein the ejecting block includes vacuum holes positioned and adapted to supply a vacuum force to the UV-sensitive tape.

6. The apparatus of claim 1, wherein each of the plurality of ejecting pins includes:
a pin holder having a hollow area;
a pin head located in the hollow area of the pin holder; and
an elastic member positioned in the hollow area of the pin holder below the pin head,
wherein an upper part of the pin head is caused to protrude from the pin holder by an elastic force from the elastic member.

7. A method of separating an integrated circuit (IC) chip from a semiconductor wafer supported on a UV-sensitive tape:
applying a vacuum force to a top surface of the IC chip with a chip transferring tool;
pushing the IC chip upward from the wafer by applying a plurality of point forces to the bottom surface of the UV-sensitive tape with a plurality of ejecting pins;
pressing the IC chip against the chip transferring tool by applying a surface pressure across a bottom surface of the IC chip with an ejecting block moving upward to the bottom surface of the IC chip; and
transferring the IC chip to a next place with the chip transferring tool.

8. The method of claim 7, further comprising:
applying a vacuum force to a bottom surface of the UV-sensitive tape in an area below the IC chip before pushing the IC chip upward;
reducing the adhesion of the UV-sensitive tape by exposing the UV-sensitive tape to UV rays before pushing the IC chip upward; and
removing the vacuum force from the bottom surface of the UV-sensitive tape before transferring the IC chip with the chip transferring tool.

9. The method of claim 8, wherein applying a vacuum force to a bottom surface of the UV-sensitive tape in an area below the IC chip includes applying a vacuum force through a plurality of pin holes located in the ejecting block.

10. The method of claim 7, wherein applying a plurality of point forces to the bottom surface of the UV-sensitive tape with a plurality of ejecting pins includes applying a plurality of elastic point forces.

11. The method of claim 7, wherein applying a plurality of point forces to the bottom surface of the UV-sensitive tape with a plurality of ejecting pins includes driving the plurality of ejecting pins with a driving plate positioned under the ejecting pins.

12. The method of claim 7, wherein applying a plurality of point forces to the bottom surface of the UV-sensitive tape with a plurality of ejecting pins includes moving the plurality of ejecting pins vertically within an ejecting block.

13. The method of claim 7, wherein pressing the IC chip against the chip transferring tool by applying a surface pressure across a bottom surface of the IC chip with an ejecting block moving upward to the bottom surface of the IC chip includes driving the ejecting block upward with a block-driving shaft positioned under the ejecting block.

14. An integrated circuit (IC) chip separating system, comprising:
a plurality of IC chips mounted on a UV-sensitive tape;
a chip transferring tool adapted to apply a vacuum force to a top surface of at least one of the plurality of IC chip;
a means for applying a vacuum force to a bottom surface of the UV-sensitive tape below the IC chip;
a means for applying a plurality of elastic point forces to the bottom surface of the UV-sensitive tape below the at least one of the plurality of IC chips;
a means for applying a surface force to a bottom surface of the at least one of the plurality of IC chips to press the IC chip against the chip transferring tool.
